(19) United States
(12) Patent Application Publication
(10) Pub. No.: US 2025/0140661 A1
(43) Pub. Date: May 1, 2025

(54) LEAD FRAME, SEMICONDUCTOR PACKAGE INCLUDING THE SAME, AND METHOD OF MANUFACTURING THE LEAD FRAME

(71) Applicant: HAESUNG DS CO., LTD., Gyeongsangnam-do (KR)

(72) Inventors: Gwang Ryeol PARK, Gyeongsangnam-do (KR); Sung Il KANG, Gyeongsangnam-do (KR); In Seob BAE, Gyeongsangnam-do (KR); Hojun RYU, Gyeongsangnam-do (KR); Wonyoung HEO, Gyeongsangnam-do (KR); In Pyo HONG, Gyeongsangnam-do (KR); Min Young HONG, Gyeongsangnam-do (KR)

(21) Appl. No.: 18/894,114

(22) Filed: Sep. 24, 2024

(30) Foreign Application Priority Data
Oct. 26, 2023 (KR) 10-2023-0145087

(51) Int. Cl. H01L 23/495; C25D 5/18; H01L 21/48

(52) U.S. Cl. CPC H01L 23/49582; H01L 21/4821; H01L 23/4952; C25D 5/18

(57) ABSTRACT

According to one or more embodiments, a method of manufacturing a lead frame, includes processing a base metal into a base substrate having a die pad portion and a lead portion, forming a nickel plating layer on the base substrate, and forming a palladium plating layer on the base substrate, wherein the palladium plating layer is formed by an electroplating method of applying a current having an on-off square wave having an on-current period shorter than an off-current period.

### CROSS-REFERENCE TO RELATED APPLICATION

The present application claims priority and the benefit of Korean Patent Application No. 10-2023-0145087, filed on Oct. 26, 2023, in the Korean Intellectual Property Office, the entire disclosure of which is incorporated herein by reference.

### BACKGROUND

### 1. Field

One or more embodiments relate to a lead frame, a semiconductor package including the same, and a method of manufacturing the lead frame.

### 2. Description of the Related Art

A lead frame is an intermediate component that electrically connects a semiconductor chip to an external device such as a printed circuit board. The lead frame may serve to support the semiconductor chip, and the semiconductor chip and the lead frame may be electrically connected through wire bonding or solder bumps.

The lead frame may be provided by laminating a nickel layer and a palladium layer on a base substrate made of a copper material to ensure high reliability, and then plating a gold or gold-silver alloy on the entire surface, and such a lead frame is referred to as a pre-plated frame (PPF).

In the case of a lead frame with a conventional PPF structure, a gold or gold-silver plating layer arranged on a top layer requires a high gold content and a high plating thickness to prevent diffusion on a lower layer and secure reliability of wire bonding. When applying a gold or gold-silver alloy plating layer with satisfactory reliability, there is a problem in that the manufacturing cost of the gold or gold-silver alloy plating layer accounts for 50% or more of the total manufacturing cost.

### SUMMARY

One or more embodiments include a lead frame and a method of manufacturing the lead frame, and include a lead frame which may reduce costs and have high reliability, a semiconductor package including the same, and a method of manufacturing the lead frame.

Additional aspects will be set forth in part in the description which follows and, in part, will be apparent from the description, or may be learned by practice of the presented embodiments of the present disclosure.

According to one or more embodiments, a lead frame includes a base substrate having a die pad portion and a lead portion, a nickel plating layer arranged on the base substrate and including nickel, and a palladium plating layer arranged on the nickel plating layer, including palladium, and having a thickness of 2 nm to 20 nm, wherein the palladium plating layer satisfies the following condition (1).

(1) After heating the lead frame at 340° C. for 1 minute, the amount of nickel (Ni) detected on the surface of the lead frame by X-ray photoelectron spectroscopy (XPS) analysis is 1.0 at % or less.

In an embodiment, the base substrate includes copper or a copper alloy, and the palladium plating layer may satisfy the following condition (2).

(2) After heating the lead frame at 340° C. for 1 minute, the amount of copper (Cu) detected on the surface of the lead frame by X-ray photoelectron spectroscopy (XPS) analysis is 1.0 at % or less.

In an embodiment, a thickness of the nickel plating layer may be 10 to 200 times a thickness of the palladium plating layer.

In an embodiment, the palladium plating layer may further include at least one additive from among nickel (Ni), copper (Cu), selenium (Se), cobalt (Co), molybdenum (Mo), ruthenium (Ru), tin (Sn), indium (In), and silver (Ag), and a fraction of the additive may be less than 5 wt % of the total amount.

In an embodiment, the nickel plating layer may have a rough surface, and a surface roughness of the nickel plating layer may be in a range of 0.1 μm to 0.5 Mm.

According to one or more embodiments, a semiconductor package includes a lead frame; and a semiconductor chip arranged on a die pad portion.

According to one or more embodiments, a method of manufacturing a lead frame, includes processing a base metal into a base substrate having a die pad portion and a lead portion, forming a nickel plating layer on the base substrate, and forming a palladium plating layer on the base substrate, wherein the palladium plating layer is formed by an electroplating method of applying a current having an on-off square wave having an on-current period shorter than an off-current period.

In an embodiment, the palladium plating layer may be formed by electroplating under the condition of a current density of 1 ADS to 3.5 ADS.

In an embodiment, the on-current period may be 5 μsec to 20 μsec, and the off-current period may be 30 μsec to 50 μsec.

In an embodiment, the total applied time of the on-off square wave may be 1 second to 10 seconds.

In an embodiment, a palladium plating solution forming the palladium plating layer may include 1 g/L to 10 g/L of palladium metal ions.

In an embodiment, the palladium plating solution forming the palladium plating layer may include an additive including at least one from among nickel, copper, selenium, tin, ruthenium, and indium.

In an embodiment, the method of manufacturing a lead frame further includes roughening the surface of the nickel plating layer, wherein the surface roughness of the nickel plating layer may be 0.1 μm to 0.5 μm.

In an embodiment, the palladium plating layer may have a thickness of 2 nm to 20 nm.

According to one or more embodiments, a solder ball includes a base ball, a nickel plating layer covering the base ball and including nickel, and a palladium plating layer arranged on the nickel plating layer, including palladium, and having a thickness of 2 nm to 20 nm, wherein the palladium plating layer satisfies the following conditions (1).

(1) After heating the lead frame at 340° C. for 1 minute, the amount of nickel (Ni) detected on the surface of the lead frame by X-ray photoelectron spectroscopy (XPS) analysis is 1.0 at % or less.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a schematic cross-sectional view of a semiconductor package manufactured using a lead frame according to an embodiment;

FIG. 2 is a schematic cross-sectional view of a lead frame according to an embodiment;

FIG. 3 is an enlarged view of part II of FIG. 2;

FIG. 4 is a cross-sectional view schematically showing a part of a lead frame according to another embodiment;

FIG. 5 is a flowchart illustrating a method of manufacturing a lead frame according to an embodiment;

FIGS. 6 to 9 are cross-sectional views sequentially showing a method of manufacturing a lead frame;

FIG. 10 is a graph showing the amount of current over time when a palladium plating layer is formed according to an embodiment;

FIG. 11 is a cross-sectional view schematically showing a solder ball formed according to an embodiment;

FIG. 12 is a photograph showing a cross-section of a portion of a lead frame formed according to an embodiment;

FIG. 13 is a photograph showing a cross-section of a portion of a lead frame according to a comparative example;

FIGS. 14A and 14B are graphs illustrating data obtained by analyzing X-ray photoelectron spectroscopy (XPS) before and after heat treatment with respect to a lead frame formed according to an embodiment; and

FIGS. 15A and 15B are graphs illustrating data obtained by analyzing X-ray photoelectron spectroscopy (XPS) before and after heat treatment with respect to a lead frame formed according to a comparative example.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The present invention may apply various transforms and have various embodiments, and particular embodiments are illustrated in the drawings and will be described in detail in the detailed description with reference to the illustrated drawings. The effects and features of the present invention, and methods of achieving the effects and features, will become apparent with reference to the embodiments described in detail with reference to the drawings. However, the present invention is not limited to the embodiments disclosed below, but may be implemented in various forms.

Hereinafter, embodiments of the present invention will be described in detail with reference to the accompanying drawings, and the same or corresponding components will be denoted by the same reference numerals and redundant descriptions thereof will be omitted.

In the following embodiments, terms such as first, second, and the like are used for the purpose of distinguishing one component from another component, not for the limited meaning.

In the following embodiments, the expression of the singular includes the expression of the plural, unless the context clearly indicates otherwise.

In the following embodiments, terms such as include or have mean that the features or components described in the disclosure exist, and do not exclude in advance the possibility of adding one or more other features or components.

In the following embodiments, when a part of a layer, region, component, etc. is said to be above or on another part, it does not only include a case that the one part is directly on top of the other part, but also includes a case that another layer, region, component, or the like is placed therebetween.

In the drawings, the sizes of components may be exaggerated or reduced for convenience of explanation. For example, since the size and thickness of each component shown in the drawings are arbitrarily shown for convenience of explanation, the present invention is not necessarily limited to those illustrated.

When some embodiments may be implemented in various forms, a specific process sequence may be performed differently from the order described. For example, two processes described in succession may be performed substantially simultaneously, or may be performed in the opposite order to the order described.

In the following embodiments, when a layer, a region, a component, and the like are connected to each other, it does not only include a case that the layer, the region, and the component are directly connected to each other, but also includes a case that another layer, another region, another component, or the like is placed therebetween to be indirectly connected to each other. For example, in the disclosure, when a layer, region, component, etc. are electrically connected to each other, it means a case that the layer, region, component, etc. are directly electrically connected to each other, as well as a case that another layer, region, component, etc. are placed therebetween to be indirectly electrically connected to each other.

Hereinafter, embodiments will be described in detail with reference to the accompanying drawings, and the same or corresponding components will be denoted by the same reference numerals and redundant descriptions thereof will be omitted.

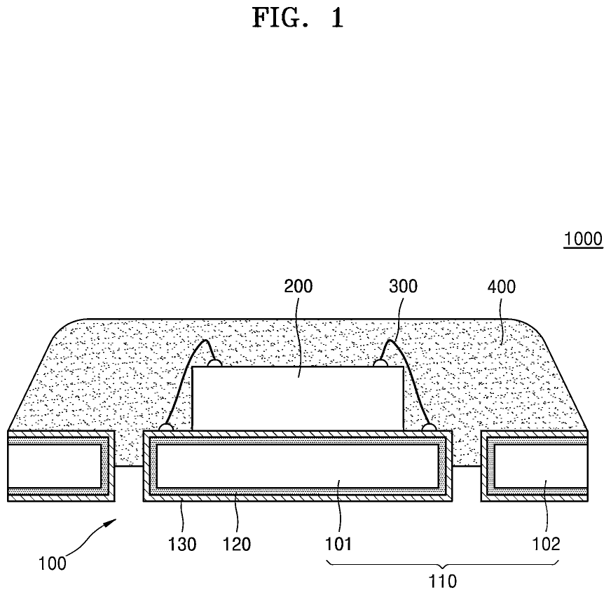

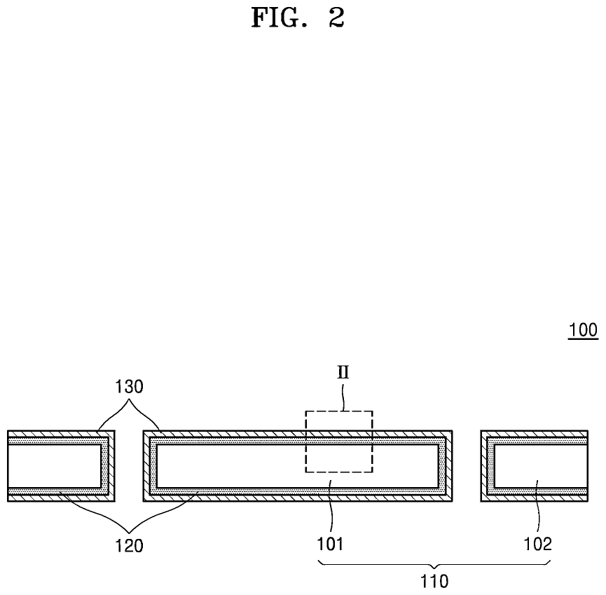

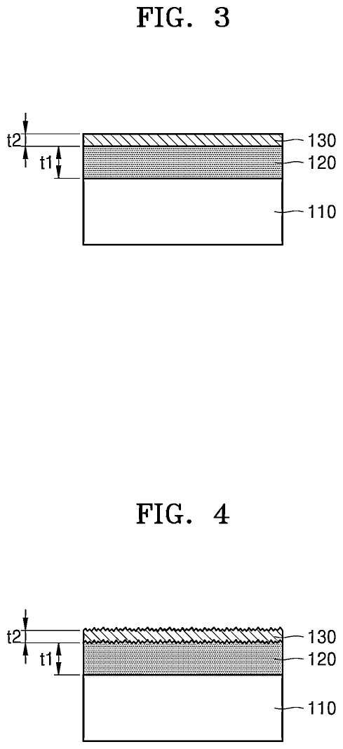

FIG. 1 is a schematic cross-sectional view of a semiconductor package manufactured using a lead frame according to an embodiment. FIG. 2 is a schematic cross-sectional view of a lead frame according to an embodiment. FIG. 3 is an enlarged view of part II of FIG. 2.

Referring to FIG. 1, a semiconductor package 1000 according to an embodiment may include a lead frame 100, a semiconductor chip 200, bonding wires 300 connecting the semiconductor chip 200 with the lead frame 100, and a mold resin 400.

Referring to FIGS. 2 and 3, a lead frame 100 according to an embodiment includes a base substrate 110 having a die pad portion 101 and lead portions 102, a nickel plating layer 120 including nickel (Ni), and a palladium plating layer 130 on the nickel plating layer 120, including a palladium (Pd), and having a thickness of 2 nm to 20 nm. In this embodiment, the palladium plating layer 130 may be the uppermost layer or the outermost layer of the lead frame 100.

The base substrate 110 includes the die pad portion 101 and the lead portions 102. The semiconductor chip 200 is attached to a top surface of the lead frame 100 corresponding to the die pad portion 101. The lead portion 102 may be formed in plural, and the top surface of the lead frame 100 corresponding to the lead portions 102 may be connected to the semiconductor chip 200 by the bonding wires 300. Although not illustrated, a bottom surface of the lead frame 100 corresponding to the lead portions 102 may be connected to an external device (not illustrated) through a solder ball (not illustrated). Accordingly, the electric signal output from the semiconductor chip 200 may be transmitted to an external device through the lead portion 102, and an electric signal input from the external device to the lead portion 102 may be transmitted to the semiconductor chip 200.

The base substrate 110 may include a metal material. The base substrate 110 may include copper (Cu) or a copper alloy material. For example, the base substrate 110 may be configured by using copper (Cu) as a main raw material and additionally including iron, zinc, and/or phosphorus.

In some embodiments, the base substrate 110 may include a copper alloy containing 97.4% copper (Cu), 2.4% iron, 0.13% zinc, and 0.03% others. The base substrate 110 may have a thickness of approximately 100 μm to 150 μm.

The base substrate 110 may be prepared in a shape including the die pad portion 101 and the lead portion 102 by processing a base metal made of such a metal material.

The nickel plating layer 120 may be formed to at least partially surround a top surface, a bottom surface, and side surfaces of the base substrate 110. The nickel plating layer 120 may be arranged on at least a part of a top surface, a bottom surface, and side surfaces of the die pad portion 101 of the base substrate 110. In addition, the nickel plating layer 120 may be arranged on at least a part of a top surface, a bottom surface, and side surfaces of the lead portion 102 of the base substrate 110.

The nickel plating layer 120 may include nickel (Ni) or a nickel alloy. When the nickel plating layer 120 includes a nickel alloy, metals that may be added to nickel may include at least one of palladium (Pd), copper (Cu), cobalt (Co), molybdenum (Mo), ruthenium (Ru), tin (Sn), indium (In), and silver (Ag), and the sum of fractions thereof may not exceed about 40 wt % of the total amount.

The nickel plating layer 120 may prevent copper oxide or copper sulfide from being generated on the surface of the base substrate 110 due to diffusion of copper or a copper alloy used as a material of the base substrate 110.

The nickel plating layer 120 may have a thickness t1 of about 250 nm to about 1000 nm (i.e., about 0.25 μm to about 1 μm). When the thickness t1 of the nickel plated layer 120 is less than 0.25 μm, the effect of preventing copper diffusion may be insufficient. Considering the economic cost and process time, the thickness of the nickel plating layer 120 is preferably 1 μm or less. A thickness of the nickel plating layer 120 may be 10 times to 200 times a thickness of the palladium plating layer 130.

As the nickel plating layer 120 is formed on a bottom surface of the die pad portion 101 and a bottom surface of the lead portion 120, a process of forming a tin or tin alloy plating layer performed before a soldering process for assembling the lead frame 100 to an external device becomes unnecessary. Since the nickel plating layer 120 forms a solder component and an intermetallic compound (IMC) layer during soldering, reliability of the soldering process may be ensured.

In general, in a lead frame that does not form the nickel plating layer 120, a process of forming a plating layer of tin or tin alloy in a region where soldering is performed is introduced to secure the reliability of soldering.

In this embodiment, since the nickel plating layer 120 is introduced, a separate tin or tin alloy plating layer may not be formed in a region where soldering is performed, thereby reducing process time and cost.

The palladium plating layer 130 may be formed on the nickel plating layer 120. The palladium plating layer 130 may be formed to at least partially surround a top surface, a bottom surface, and side surfaces of the base substrate 110. That is, the palladium plating layer 130 may be arranged on at least a part of a top surface, a bottom surface, and side surfaces of the die pad portion 101 of the base substrate 110. In addition, the palladium plating layer 130 may be arranged on at least a part of a top surface, a bottom surface, and side surfaces of the lead portion 102 of the base substrate 110.

The palladium plating layer 130 may include palladium (Pd) or a palladium alloy. When the palladium plating layer 130 includes a palladium alloy, additives that may be added to palladium may include at least one of nickel (Ni), copper (Cu), selenium (Se), cobalt (Co), molybdenum (Mo), ruthenium (Ru), tin (Sn), indium (In), and silver (Ag), and the sum of fractions thereof may not exceed about 5 wt % of the total amount.

The palladium plating layer 130 may prevent a material such as nickel or copper included in the nickel plating layer 120 or the base substrate 110 arranged thereinward from being diffused to the surface of the lead frame 100.

The palladium plating layer 130 according to the present embodiment may be provided as a high-density ultra-thin film. That is, even if the palladium plating layer 130 according to the present embodiment is provided with a high density and thus provided with a very thin thickness of nanometers or so, materials such as nickel and copper included in the nickel plating layer 120 or the base substrate 110 arranged thereinward may not diffuse to the surface of the lead frame 100.

The thickness t2 of the palladium plating layer 130 may be about 2 nm to about 20 nm (i.e., 0.002 μm to 0.02 μm), preferably about 5 nm to about 15 nm. Process time and process cost may be reduced by the small thickness t2 of the palladium plating layer 130.

The palladium plating layer 130 according to the present embodiment may satisfy the following conditions.

(1) After heating the lead frame at 340° C. for 1 minute, the amount of nickel (Ni) detected on the surface of the lead frame by X-ray photoelectron spectroscopy (XPS) analysis is 1.0 at % or less.

(2) After heating the lead frame at 340° C. for 1 minute, the amount of copper (Cu) detected on the surface of the lead frame by X-ray photoelectron spectroscopy (XPS) analysis is 1.0 at % or less.

As described above, the palladium plating layer 130 according to the present embodiment may be uniformly provided at a high density to prevent a material such as nickel and copper from being diffused to the surface of the lead frame 100 in the layers arranged inward from the palladium plating layer 130 even after thermal stress is applied. In addition, the palladium plating layer 130 has an ultra-thin thickness of about 2 nm to about 20 nm and is provided at high density, and thus, the cost of forming the palladium plating layer 130 may be reduced.

FIG. 4 is a cross-sectional view schematically showing a part of a lead frame according to another embodiment. In FIG. 4, the same reference numerals as in FIG. 3 denote the same members.

Referring to FIG. 4, the lead frame 100 includes a base substrate 110, a nickel plating layer 120, and a palladium plating layer 130 having a thickness of about 2 nm to about 20 nm. A thickness t1 of the nickel plating layer 120 may be about 10 times to about 200 times a thickness t2 of the palladium plating layer 130.

In the present embodiment, the surface of the nickel plating layer 120 may be roughly provided through a roughening process. As the surface of the nickel plating layer 120 is roughly formed, a contact area with the palladium plating layer 130 formed on the nickel plating layer 120 increases, and thus adhesion between the nickel plating layer 120 and the palladium plating layer 130 may be improved. In addition, adhesion with an epoxy applied for adhesion to the semiconductor chip (200 in FIG. 1) arranged on the lead frame 100 and a mold resin 400 applied for sealing may be strengthened.

The surface roughness (Ra) of the nickel plating layer 120 may preferably be 0.1 μm to 0.5 μm. When the surface roughness of the nickel plating layer 120 is less than 0.1 μm, there may be no effect in adhesion with the mold resin 400 or the like, and when the surface roughness exceeds 0.5 μm, the nickel plating layer 120 may be unstable and a peeling phenomenon may occur. The roughening treatment of the nickel plating layer 120 may be performed by an electroplating method or a wet etching method.

The surface of the palladium plating layer 130 may be formed rough by reflecting the surface roughness of the nickel plating layer 120. Since the thickness t2 of the palladium plating layer 130 is less than the thickness t1 of the nickel plating layer 120, the surface roughness of the nickel plating layer 120 may be reflected on the top surface of the palladium plating layer 130 even if a separate roughening process is not performed. As the surface of the palladium plating layer 130 is formed rough, adhesion to additional elements formed in direct contact with the palladium plating layer 130 may be improved.

In addition, as the surface of the palladium plating layer 130 is formed to be rough, the adhesion with the epoxy applied for adhesion to the semiconductor chip (200 in FIG. 1) arranged on the lead frame 100 and the mold resin 400 applied for sealing may also be strengthened.

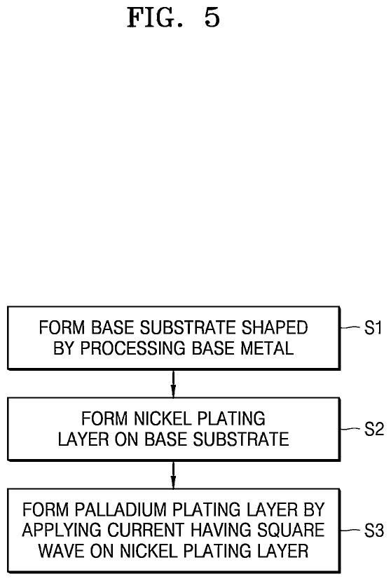

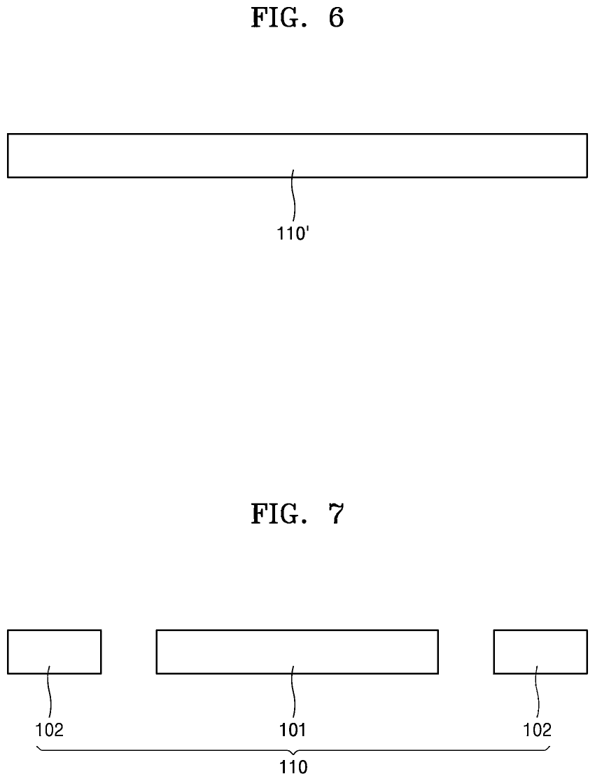

FIG. 5 is a flowchart illustrating a method of manufacturing a lead frame according to an embodiment. FIGS. 6 to 9 are cross-sectional views sequentially showing a method of manufacturing a lead frame. FIG. 10 is a graph showing the amount of current over time when a palladium plating layer is formed according to an embodiment.

Referring to FIG. 5, a method of manufacturing a lead frame according to an embodiment includes an operation S1 of forming a base substrate shaped by processing a base metal, an operation S2 of forming a nickel plating layer on the base substrate, and an operation S3 of forming a palladium plating layer by using an electroplating method using a square wave current.

First, referring to FIG. 6, a base metal 110′ made of a metal material is prepared. The base metal 110′ may include copper (Cu) or a copper alloy material. For example, the base metal 110′ may be configured by using copper (Cu) as a main raw material and additionally including iron, zinc, and/or phosphorus, etc. In some embodiments, the base metal 110′ may include a copper alloy containing 97.4% copper (Cu), 2.4% iron, 0.13% zinc, and 0.03% others. The base metal 110′ may have a thickness of approximately 100 μm to 150 μm.

Next, referring to FIG. 7, the base metal 110′ is processed to form a base substrate 110 provided with a die pad portion 101 and lead portions 102 (S1).

In order to process the base substrate 110, a metal etching process may be performed after forming a photoresist pattern on the base substrate 110. The etching process may be a wet process. Alternatively, a stamping method may be performed to process the base substrate 110. Alternatively, in order to process the base substrate 110, a process of forming a pattern by irradiating a laser beam may be performed. Through this process, the base substrate 110 provided with the die pad portion 101 and the lead portions 102 may be formed.

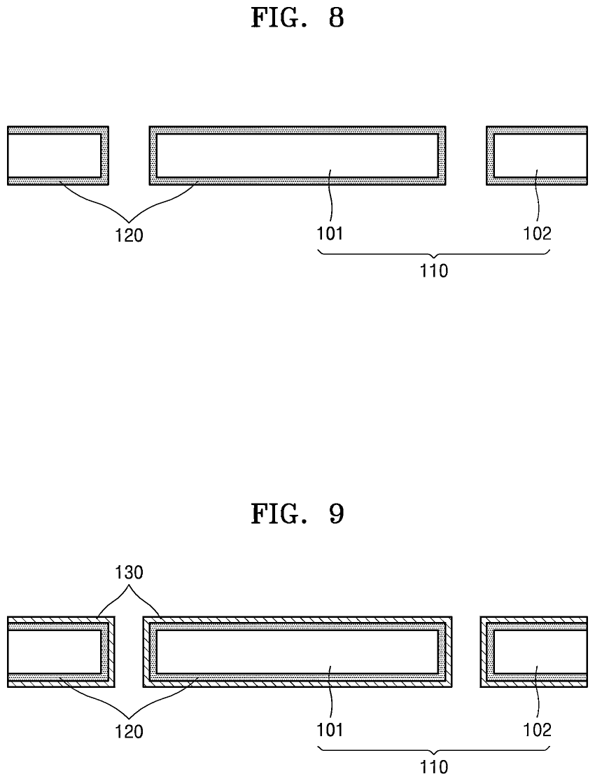

Next, referring to FIG. 8, a nickel plating layer 120 is formed on the base substrate 110 (S2).

The nickel plating layer 120 may be formed to at least partially surround a top surface, a bottom surface, and side surfaces of the base substrate 110. Before forming the nickel plating layer 120, pre-processing processes such as cleaning and polishing the base substrate 110 may be performed, and then, the nickel plating layer 120 may be formed using an electroplating method. For example, the base substrate 110 may be immersed in a metal ion solution including nickel ions to apply high current density to perform electroplating. The nickel plating layer 120 may be formed by using various types of electroplating methods. For example, the nickel plating layer 120 may be formed in various ways, such as an electroplating method that applies a direct current or an electroplating method that applies an alternating current.

Next, roughening processing may be performed to roughen the surface of the nickel plating layer 120. The roughening processing may be performed by an electroplating method or a wet etching method. For example, a nickel plating layer 120 with a rough surface may be formed through rapid growth by applying a high current density of 10 ASD (Ampere/100 cm²) or more, using a drug based on nickel 2-10 g/L, ammonium sulfate 10-30 g/L, sodium sulfate 20-50 g/L, sodium chloride 10-20 g/L, and boric acid 10-25 g/L. Alternatively, after the nickel plating layer 120 is formed to a predetermined thickness, the surface of the nickel plating layer 120 may be roughly processed through a wet etching method.

Next, referring to FIG. 9, a palladium plating layer 130 is formed on the base substrate 110 (S3).

The palladium plating layer 130 may be formed to at least partially surround a top surface, a bottom surface, and side surfaces of the base substrate 110. The palladium plating layer 130 may be formed on the nickel plating layer 120.

In the present embodiment, the palladium plating layer 130 may be formed by an electroplating method, and may be formed by applying a current having square wave waveform. That is, the waveform of a current applied during plating of the palladium plating layer 130 is provided as a square wave (rectangular wave), and the square wave may be provided as a waveform as shown in FIG. 10.

Referring to FIG. 10, the plating current according to the present embodiment may include a square wave which repeatedly applies a predetermined plating current for an on-current time T_on and then not for an off-current time T_off. In the present specification, such a square wave is referred to as an on-off square wave.

In the present embodiment, the on-current time T_on may be shorter than the off-current time T_off. A reduction action may occur at an on-current time T_on to which a current is applied, and reduced palladium atoms may form a nucleus at an off-current time T_off.

By controlling such a nucleation density, the density and uniformity of the palladium plating layer may be adjusted. When the on-current time T_on is longer than the off-current time T_off, the nucleation density may be increased to cause a rough and non-uniform coating.

In this embodiment, the on-current time T_on is shorter than the off-current time T_off, and thus, the palladium plating layer 130 according to this embodiment may be formed uniformly with high density. In some embodiments, the on-current time T_on may be 5 μsec to 20 μsec. In some embodiments, the off-current time T_off may be 30 μsec to 50 μsec.

The palladium plating layer 130, according to the present embodiment, may be formed to have a thickness of 2 nm to 20 nm. To this end, the total applied time T_total of the current having the square wave may be about 1 second to 10 seconds. The thickness of the palladium plating layer 130 may be controlled by adjusting the total applied time T_total.

In addition, in this embodiment, the current density applied when forming the palladium plating layer 130 may be about 1 ASD to 3.5 ASD. When the current density exceeds 3.5 ASD, the nucleation density increases so that the particles grow unevenly, and thus pores may be formed in the palladium plating layer 130. When the current density is less than 1 ASD, the nucleation density is so low that discontinuous coating may be caused.

The composition of the plating solution is also important to control the nucleation density.

In the present embodiment, the palladium metal ions may be preferably included in the palladium plating solution in about 1 g/L to about 10 g/L, or about 3 g/L to about 6 g/L. When the amount of palladium metal ions exceeds 10 g/L, high nucleation density may be caused to be not uniformly formed, and when the amount of palladium metal ions is less than 1 g/L, the nucleation density may be so low that discontinuous coating may be caused.

In this embodiment, the pH range of the palladium plating solution may be about 4 pH to about 8 pH. That is, the palladium plating solution may be provided with weak acidity, neutrality, and weak alkalinity. When the pH of the palladium plating solution exceeds 8, current efficiency increases, and it may be difficult to form a high-density thin film. When the pH of the palladium plating solution is less than 4, the hydrogen reduction reaction may become active and hydrogen bubbles may be generated, thereby reducing current efficiency. The palladium plating solution may include a conductive salt to adjust the pH. The palladium plating solution may include at least one of ammonium sulfate, ammonium chloride, ammonium nitrate, and an ammonium compound as a conductive salt.

In the present embodiment, an additive including at least one of nickel, copper, selenium, tin, ruthenium, and indium may be added to the palladium plating solution. The additive may be included in about 0.1 ppm to about 50 ppm in the plating solution. The additive may function as a reduction accelerator. The additive may be first adsorbed on the surface of the nickel plating layer 120 when the palladium plating layer 130 is formed to accelerate reduction of palladium.

In this embodiment, when forming the palladium plating layer, the temperature of the palladium plating solution may be about 50° C. to about 60° C. When the temperature of the palladium plating solution exceeds 60° C., resistance of the plating solution decreases, and current efficiency increases, and thus it may be difficult for the thin film to be formed at high density. When the temperature of the palladium plating solution is less than 50° C., the current efficiency is lowered, and a thin film may be formed discontinuously.

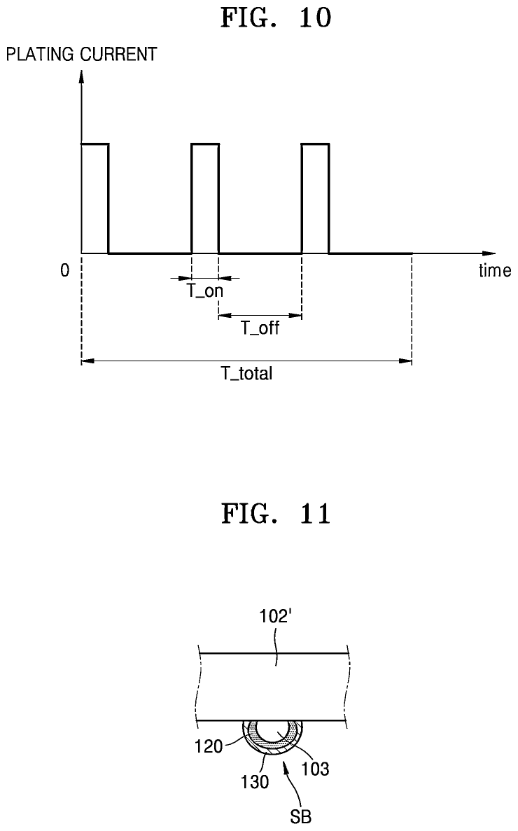

FIG. 11 is a cross-sectional view schematically showing a solder ball formed according to an embodiment.

Referring to FIG. 11, a solder ball SB may be a member arranged on a bottom surface of a lead portion 102′ of a lead frame, thereby connecting the lead frame to an external device (not shown).

The solder ball SB according to an embodiment includes: a base ball 103; a nickel plating layer 120 covering the base ball 103, and including nickel; and a palladium plating layer 130 arranged on the nickel plating layer, including palladium, and having a thickness of 2 nm to 20 nm, wherein the palladium plating layer may satisfy the following conditions (1).

(1) After heating the lead frame at 340° C. for 1 minute, the amount of nickel (Ni) detected on the surface of the lead frame by X-ray photoelectron spectroscopy (XPS) analysis is 1.0 at % or less.

The base ball 103 may be provided in a spherical shape, and may include a metal material. The base ball 103 may include copper (Cu) or a copper alloy material. For example, the base ball 103 may be configured by using copper (Cu) as a main raw material and additionally including iron, zinc, and/or phosphorus, etc.

The nickel plating layer 120 and the palladium plating layer 130 may be formed using materials, thicknesses, and manufacturing methods described with reference to FIGS. 1 to 10.

According to the present embodiment, the solder ball SB introduces a high-density ultra-thin palladium plating layer 130 as an outermost layer, and thus has superior properties in preventing solder bleeding than a solder ball in which gold (Au) is introduced as the outermost layer.

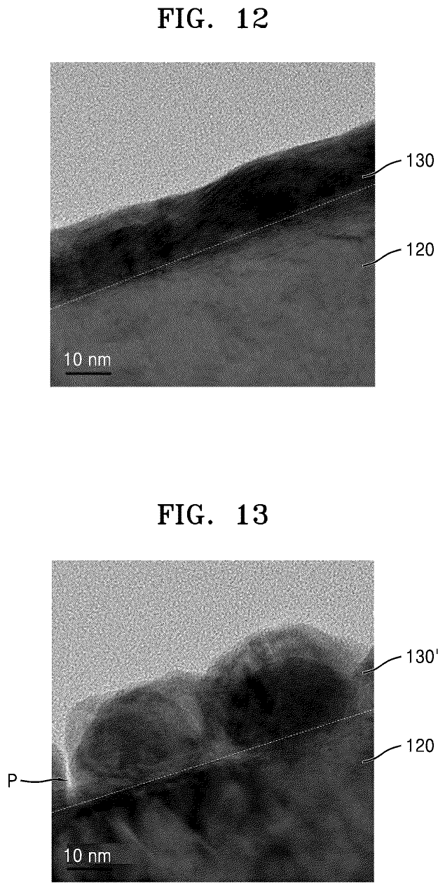

FIG. 12 is a photograph showing a cross-section of a portion of a lead frame formed according to an embodiment. FIG. 13 is a photograph showing a cross-section of a portion of a lead frame according to a comparative example.

Referring to FIG. 12, a nickel (Ni) plating layer 120 is formed on a copper (Cu) substrate, and a palladium plating layer 130 is sequentially formed on the nickel plating layer 120, thereby manufacturing a lead frame. Referring to FIG. 13, a nickel (Ni) plating layer 120 is formed on a copper (Cu) substrate, and a palladium plating layer 130′ is sequentially formed on the nickel plating layer 120, thereby manufacturing a lead frame. The nickel plating layer 120 of FIGS. 12 and 13 is formed to have a thickness of about 50 nm.

The palladium plating layer 130 of FIG. 12 was electroplated using on-off square waves according to the present embodiment. In this case, the current density was 2 ASD, the on-current period was 10 μsec, and the off-current period was 40 μsec, and electroplating was performed for a total of 8 seconds. The palladium plating layer 130 of FIG. 13 has a thickness of about 15 nm.

The palladium plating layer 130′ of FIG. 13 is formed by forming the palladium plating layer 130′ different from the conditions of the present embodiment, and the palladium plating layer 130′ has a thickness of about 25 nm.

It may be seen that the palladium plating layer 130 of FIG. 12 according to the present embodiment is uniformly and densely formed without pores. Although the palladium plating layer 130′ of FIG. 13 is formed to have a thickness greater than that of the palladium plating layer 130 of FIG. 12, it may be seen that pores P are formed in the palladium plating layer 130′ of FIG. 13, and the palladium plating layer 130′ is not uniformly formed.

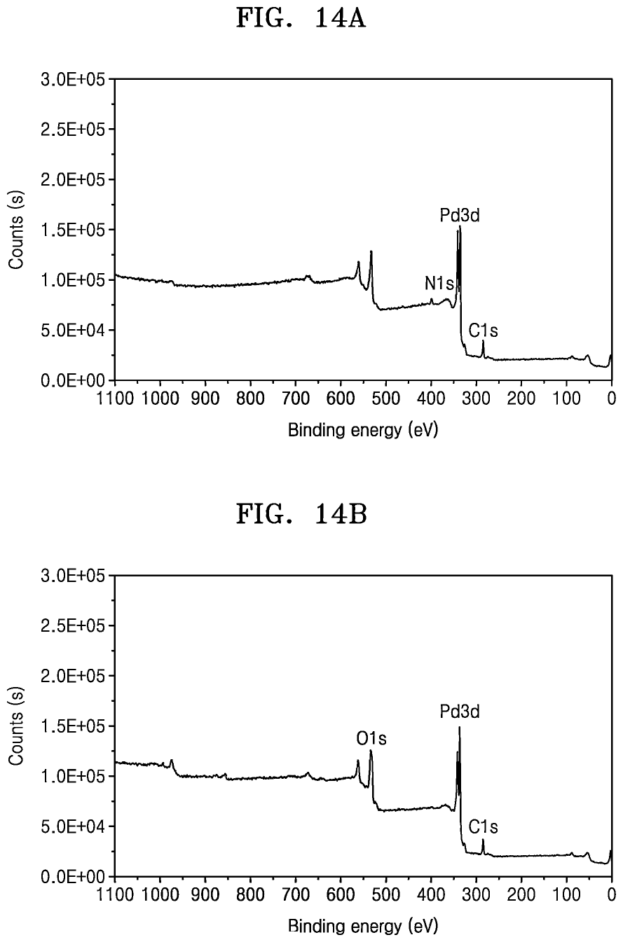

FIGS. 14A and 14B are graphs illustrating data obtained by analyzing X-ray photoelectron spectroscopy (XPS) before and after heat treatment with respect to a lead frame formed according to an embodiment.

FIGS. 14A and 14B show data on lead frames in which a nickel plating layer and a palladium plating layer are formed on a copper base substrate under the same conditions as the sample of FIG. 12.

Referring to FIG. 14A, copper (Cu) and nickel (Ni) are not detected on the surface of the lead frame before a thermal treatment. (0.00 at %)

Referring to FIG. 14B, after thermal treatment at 340° C. for 1 minute, copper (Cu) and nickel (Ni) are not detected on the surface of the lead frame. (0.00 at %)

That is, since the lead frame according to the embodiment has a high density palladium plating layer, it may be confirmed that copper and nickel are not diffused to the surface of the lead frame.

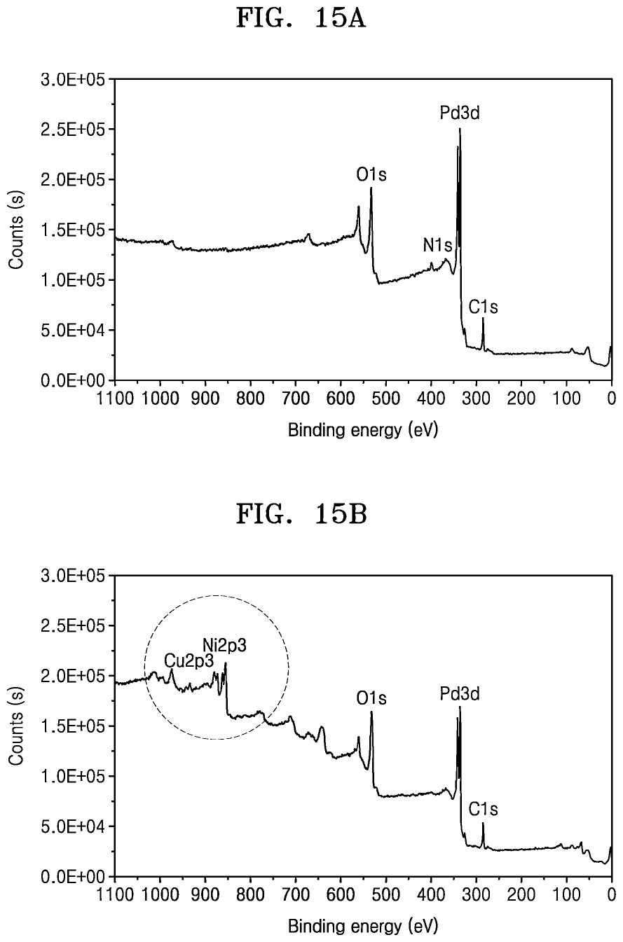

FIGS. 15A and 15B are graphs illustrating data obtained by analyzing X-ray photoelectron spectroscopy (XPS) before and after heat treatment with respect to a lead frame formed according to a comparative example.

FIGS. 15A and 15B show data on lead frames in which a nickel plating layer and a palladium plating layer are formed on a copper base substrate under the same conditions as the sample of FIG. 13.

Referring to FIG. 15A, copper (Cu) and nickel (Ni) are not detected on the surface of the lead frame before a thermal treatment. (0.00 at %)

Referring to FIG. 15B, after thermal treatment at 340° C. for 1 minute, 2.65 at % copper (Cu) was detected on the surface of the lead frame and 15.31 at % nickel (Ni) was detected.

As described above, in the lead frame according to the comparative example, more than 1.0 at % nickel (Ni) was detected after thermal treatment, and a significant amount of nickel (Ni) was detected after thermal treatment compared to before thermal treatment. When pores are formed in the palladium plating layer as in the comparative example, it may be confirmed that nickel is diffused to the surface of the lead frame.

As described above, the lead frame according to the embodiment may secure reliability while reducing costs by having a high-density, ultra-thin palladium layer as the outermost layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims.

What is claimed is:

1. A lead frame comprising:
a base substrate having a die pad portion and a lead portion;
a nickel plating layer arranged on the base substrate and including nickel; and
a palladium plating layer arranged on the nickel plating layer, including palladium, and having a thickness of 2 nm to 20 nm, wherein the palladium plating layer satisfies the following condition (1).
(1) After heating the lead frame at 340° C. for 1 minute, the amount of nickel (Ni) detected on the surface of the lead frame by X-ray photoelectron spectroscopy (XPS) analysis is 1.0 at % or less.

2. The lead frame of claim 1, wherein the base substrate comprises copper or a copper alloy, and the palladium plating layer satisfies the following condition (2).
(2) After heating the lead frame at 340° C. for 1 minute, the amount of copper (Cu) detected on the surface of the lead frame by X-ray photoelectron spectroscopy (XPS) analysis is 1.0 at % or less.

3. The lead frame of claim 1, wherein a thickness of the nickel plating layer is 10 to 200 times a thickness of the palladium plating layer.

4. The lead frame of claim 1, wherein the palladium plating layer further comprises at least one additive from among nickel (Ni), copper (Cu), selenium (Se), cobalt (Co), molybdenum (Mo), ruthenium (Ru), tin (Sn), indium (In), and silver (Ag), and a fraction of the additive is less than 5 wt % of the total amount.

5. The lead frame of claim 1, wherein the nickel plating layer has a rough surface, and a surface roughness of the nickel plating layer is in a range of 0.1 μm to 0.5 μm.

6. A method of manufacturing a lead frame, the method comprising:
processing a base metal into a base substrate having a die pad portion and a lead portion;
forming a nickel plating layer on the base substrate; and
forming a palladium plating layer on the base substrate, wherein
the palladium plating layer is formed by an electroplating method of applying a current having an on-off square wave having an on-current period shorter than an off-current period.

7. The method of claim 6, wherein the palladium plating layer is formed by electroplating under the condition of a current density of 1 ADS to 3.5 ADS.

8. The method of claim 6, wherein the on-current period is 5 μsec to 20 μsec, and the off-current period is 30 μsec to 50 μsec.

9. The method of claim 6, wherein the total applied time of the on-off square wave is 1 second to 10 seconds.

10. The method of claim 6, wherein a palladium plating solution forming the palladium plating layer comprises palladium metal ions of 1 g/L to 10 g/L.

11. The method of claim 6, wherein a palladium plating solution forming the palladium plating layer comprises an additive including at least one from among nickel, copper, selenium, tin, ruthenium, and indium.

12. The method of claim 6, further comprising roughening the surface of the nickel plating layer, wherein the surface roughness of the nickel plating layer is 0.1 μm to 0.5 μm.

13. The method of claim 6, wherein the palladium plating layer has a thickness of 2 nm to 20 nm.

14. A solder ball comprising:
a base ball;
a nickel plating layer covering the base ball and including nickel; and
a palladium plating layer arranged on the nickel plating layer, including palladium, and having a thickness of 2 nm to 20 nm, wherein
the palladium plating layer satisfies the following condition (1).
(1) After heating the lead frame at 340° C. for 1 minute, the amount of nickel (Ni) detected on the surface of the lead frame by X-ray photoelectron spectroscopy (XPS) analysis is 1.0 at % or less.
